(19) United States
(12) Patent Application Publication
(10) Pub. No.: US 2024/0420963 A1
(43) Pub. Date: Dec. 19, 2024

(54) MODIFICATION OF METAL-CONTAINING SURFACES IN HIGH ASPECT RATIO PLASMA ETCHING

(71) Applicant: Lam Research Corporation, Fremont, CA (US)

(72) Inventors: He Zhang, Fremont, CA (US); Chen Li, Santa Clara, CA (US); Kevin Lai, San Jose, CA (US); Neil Macaraeg Mackie, Fremont, CA (US); Dongho Heo, Sunnyvale, CA (US)

(21) Appl. No.: 18/705,932

(22) PCT Filed: Nov. 2, 2022
(86) PCT No.: PCT/US2022/079143

§ 371 Date: Apr. 29, 2024

Related U.S. Application Data
(60) Provisional application No. 63/263,494, filed on Nov. 3, 2021.

(51) Int. Cl. H01L 21/311; H01J 37/32

(52) U.S. Cl. CPC H01L 21/31116; H01J 37/32449; H01J 37/32816; H01J 37/32899; H01J 2237/334

(57) ABSTRACT

Methods and apparatus for etching high aspect ratio features in substrates having mixed material stacks are provided herein. Methods involve using low plasma power, high chamber pressure, and/or low temperature while exposing the substrate to a metal-containing additive gas during etching using a fluorocarbon gas.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor fabrication processes involve etching certain structures, including structures having exposed surfaces that include more than one material or composition. Additionally, etching may be performed to form small feature sizes for some structures, and the reliability of the features to maintain their size and in some cases, their shape, in subsequent processes may be used to form the desired structure.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for processing substrates, the method including: providing a substrate having a mixed material stack; exposing the mixed material stack to one or more etching gases and igniting a first plasma at a first plasma power to partially etch a feature into the mixed material stack to form a partially etched mixed material stack; and exposing the partially etched mixed material stack to a second plasma having generated from igniting a metal-containing additive gas at a second plasma power, where the second plasma power is less than the first plasma power.

In various embodiments, the metal-containing additive gas includes a halogen.

In various embodiments, the metal-containing additive gas includes a metal such as any of tungsten, tin, molybdenum, and titanium.

In various embodiments, the second plasma power is less than about 1% to about 10% of the first plasma power.

In various embodiments, exposing the partially etched mixed material stack to the second plasma is performed at a first chamber pressure greater than a second chamber pressure used during the exposing of the mixed material stack to the one or more etching gases. In some embodiments, the first chamber pressure is about 1.5 times to about 4 times greater than the second chamber pressure.

In various embodiments, the exposing the partially etched mixed material stack to the second plasma is performed using a first substrate temperature less than second substrate temperature used during the exposing of the mixed material stack to the one or more etching gases. In some embodiments, the first substrate temperature is about 20° C. to about 60° C.

In various embodiments, the exposing the partially etched mixed material stack to the second plasma is performed for a duration less than about 20 seconds.

In various embodiments, the one or more etching gases include at least one gas including a fluorine and a carbon atom.

In various embodiments, the metal-containing additive gas is diluted in an inert gas. In some embodiments, metal-containing additive gas and the inert gas are co-flowed using a ratio of a flow rate of the metal-containing additive gas to a flow rate of the inert gas of about 1:40 to about 1:100. In some embodiments, the inert gas is argon or krypton.

In any of the above embodiments, the mixed material stack includes two or more layers, each layer having a composition selected from the group consisting of oxides, nitrides, carbides, and polysilicon.

In any of the above embodiments, the mixed material stack includes an ONON stack and an oxide.

In any of the above embodiments, sidewalls of the feature include two or more materials including any one or more of oxides, nitrides, carbides, and polysilicon.

In any of the above embodiments, the exposing the mixed material stack to the one or more etching gases includes exposing the mixed material stack to one or more cycles of sequentially alternating pulses of a fluorocarbon gas and a hydrogen-containing fluorocarbon gas.

In some embodiments, the exposing of the partially etched mixed material stack to the second plasma is performed every n cycles of the sequentially alternating pulses, where n is an integer equal to or greater than 1.

Another aspect involves an apparatus for processing substrates, the apparatus including: one or more process chambers, each process chamber including a chuck; a plasma generator; a first gas source for containing one or more etching gases; a second gas source for containing a metal-containing additive gas; one or more gas inlets into the process chambers and associated flow-control hardware for delivering gases from the first gas source and the second gas source to the one or more process chambers; and a controller having at least one processor and a memory, where the at least one processor and the memory are communicatively connected with one another, the at least one processor is at least operatively connected with the flow-control hardware, and the memory stores computer-executable instructions for controlling the at least one processor to at least control the flow-control hardware to: cause a substrate to be provided to a first of the one or more process chambers; cause a first plasma to be generated at a first plasma power using one or more etching gases; and cause a second plasma to be generated at a second plasma power using a metal-containing additive gas, using a second plasma power that is less than the first plasma power. For example, in some embodiments, the second plasma power is less than about 1% to about 10% of the first plasma power.

In various embodiments, the memory further stores computer-executable instructions for causing the substrate to be shuttled to a second of the one or more process chambers before causing a second plasma to be generated in the second of the one or more process chambers.

In some embodiments, a first chamber pressure of the second of the one or more process chambers is greater than a second chamber pressure of the first of the one or more process chambers. For example, in some embodiments, the first chamber pressure is about 1.5 to about 4 times greater than the second chamber pressure.

In some embodiments, the chuck holding the substrate is cooled between causing the first plasma to be generated and causing the second plasma to be generated. For example, in some embodiments, the substrate is cooled to a temperature that is about 20° C. to about 60° C.

In some embodiments, the memory further stores computer-executable instructions for causing a dilution gas to be co-flowed with the metal-containing additive gas. For example, in some embodiments, a ratio of flow rate of the metal-containing additive gas to a flow rate of the dilution gas is about 1:40 to about 1:100.

These and other aspects are described further below with reference to the drawings.

### BRIEF DESCRIPTION OF THE DRAWINGS

FIGS. 1A and 1B are side views of a feature having various materials on its sidewalls.

FIG. 1C is a top view of a substrate having features with different shapes.

FIG. 2 is a process flow diagram depicting operations in a method performed in accordance with certain disclosed embodiments.

FIGS. 3A-3C depict apparatuses for plasma etching according to various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes can involve fabrication of a variety of structures. In some cases, some structures may be formed whereby multiple alternating layers of material in a stack are formed over a substrate followed by etching vertical features into the layers of material. In some embodiments, alternating layers may be alternating oxide and nitride layers, such as used in fabrication of 3D-NAND devices. In some embodiments, some structures may involve multiple alternating layers that change composition depending on the depth of the layers of material, where sidewalls of features formed in the alternating layers include a first two alternating materials and then then a second two alternating materials, such that the point in which the alternating materials change is different depending on the depth of the alternating layers in the overall stack. In some embodiments, a portion of some features may include one material, while a portion of some features include multiple materials, and another portion includes alternating multiple materials. Additionally, some structures may include features that have sidewalls that include a first set of alternating layers, followed by a second set of alternating layers, followed by a third or more set of alternating layers, and the materials in the alternating layers or the point at which the compositions change in one sidewall of a feature may be different from that of a second sidewall within the same feature. Such features may be referred to as “mixed features”—that is, features having multiple alternating material compositions in its sidewalls.

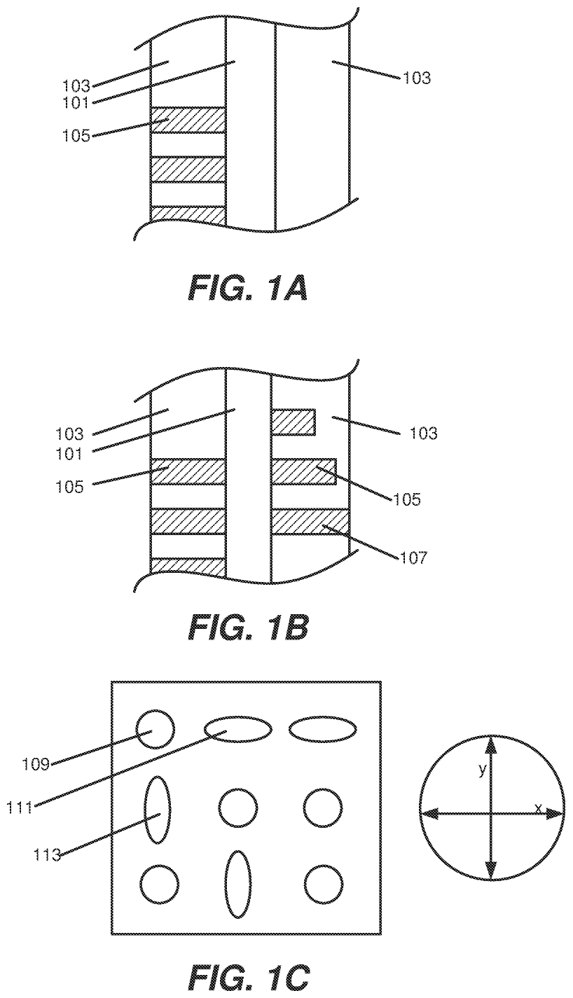

FIG. 1A shows an example cross section of a side view of a stack with negative feature 101 having sidewalls with all oxide 103 on the right sidewall and but with some oxide 103 then alternating oxide 103 and nitride 105 on the left side. FIG. 1B shows an example cross section of a side view of a stack with negative feature 101 having sidewalls with some oxide 103 and some nitride 105 as well as a third material 107, such as a carbide. While one feature is shown, it will be understood that multiple features with variations of sidewalls in each feature may be present on a single substrate. Such substrates may be difficult to etch consistently or evenly across features, both across the wafer and within the depths of the features, particularly very deep features, such as features having a depth of at least about 8000 nm.

Features may also have different sizes or shapes across a substrate, and maintaining the profile of the features and the shapes may be difficult. An example is provided in FIG. 1C, which shows a top view of a substrate with various features 109, 111, and 113 having different diameters, shapes, and x:y ratios. Additionally, such features may have a particular feature size, which may be measured by its aspect ratio, or its depth and its width. Such features may also have a particular shape, such as having vertical sidewalls, or having a circular shape from a top view, or a trench shape from a top view. Existing techniques for etching such features face various challenges, including undercutting, uneven etching along sidewalls of the features, variation of feature size during etching and in subsequent operations, pattern loading effects, uneven chipping on sidewalls, charging effects between an oxide and oxide/nitride region, variation of feature shape during etching, feature profile distortion, feature bending, and more. Additionally, it is challenging to etch different materials, different feature sizes, different feature shapes, and different feature depths uniformly using a single etching operation.

Provided herein are methods and apparatus for etching mixed features while maintaining the feature shape and size to thereby reduce pattern loading effects. Methods involve including a metal-containing gas exposure operation during etching, after etching, or both using low plasma power, low temperature, and high pressure. In various embodiments, the metal-containing gas includes tungsten. In some embodiments, the metal-containing gas includes a halogen. In various embodiments, the metal-containing gas is tungsten hexafluoride. Plasma power is modulated to prevent chipping into sidewalls of a feature; for example, at high plasma power using a metal-containing gas, the gas may act as a harsh etchant. Tungsten may cause formation of tungsten byproducts on surfaces of the sidewalls, causing variation or striation from crystallized tungsten byproducts. Where high plasma power is used during introduction of a metal-containing gas, sidewall surfaces including nitrogen or nitride in a feature may etch more quickly than oxide surfaces. As a result, modulation of plasma power can substantially affect the feature profile. Low temperature and high pressure can be used to reduce the formation of crystallized metal byproducts. In various embodiments, the metal-containing gas is diluted using an inert gas such as argon or krypton. The metal-containing gas is added during the main etching (e.g., when the main etching gases are introduced) or may be performed as a separate flash operation, inserted in short periodic exposures between etching operations. In some embodiments, the flash operation is only occasionally performed between main etching operations that are performed at high plasma. Without being bound by a particular theory, it is believed that the short exposure and modulated process conditions of the metal-containing gas causes a type of surface modification that evens out etching of the sidewalls during formation of negative features in complex mixed material stacks.

While the description below focuses on etching of certain mixed material stacks using a metal-containing additive gas, aspects of the disclosure may also be implemented in etching other materials that include one material or other structures to maintain feature profiles.

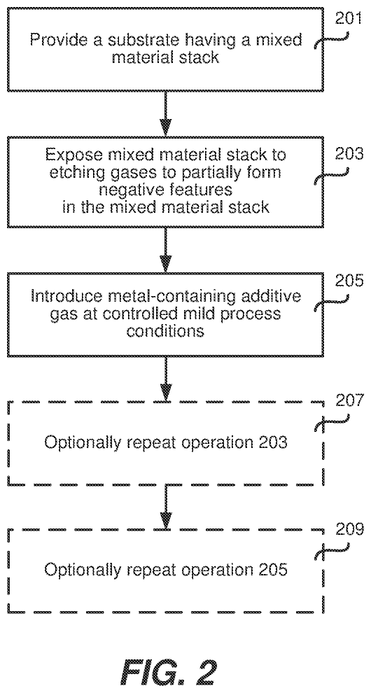

FIG. 2 provides an example process flow diagram depicting operations that may be performed in accordance with certain disclosed embodiments. In an operation 201, a substrate having a mixed material stack formed thereon is provided. The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates, and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, LEDs, photovoltaic panels and the like. The substrate may be a silicon wafer, e.g., a 200-mm wafer, a 300-mm wafer, or a 450-mm wafer, including wafers having one or more layers of material, such as dielectric, conducting, or semi-conducting material deposited thereon.

The substrate has a mixed material stack formed thereon. A mixed material stack includes two or more layers, each layer having one, two, or more materials in a single layer. Each layer may be about 100 Å to about 500 Å or up to about 50 nm in thickness. Each layer may have a different thickness. In some embodiments, a mixed material stack includes one or more of oxides, carbides, and/or nitrides. In some embodiments, a mixed material stack includes any one or more of: oxide material; nitride material; alternating layers of oxide and nitride; alternating layers of polysilicon and oxide; three alternating layers of oxide, nitride, and polysilicon; and silicon oxynitride. For example, a mixed material stack may include a ONON (oxide-nitride-oxide-nitride) stack, a OPOP (silicon oxide on polysilicon) stack, or OMOM stack (silicon oxide on metal such as tungsten, cobalt, or molybdenum) and features may be formed in such multi-layer substrates where sidewalls of the features include two or more compositions. Multi-laminate stacks may range from a bilayer (such as ON) to 5000 combined layers (such as {ON}₁₅₀).

Oxides include but are not limited to metal oxides, semiconductor oxides, and dielectric oxides. Oxides include undoped oxides and doped oxides. One example oxide is silicon oxide. One example oxide is undoped silicon dioxide. “Silicon oxide” is referred to herein as including chemical compounds including silicon and oxygen atoms, including any and all stoichiometric possibilities for SiₓO_{y}, including integer values of x and y and non-integer values of x and y. For example, “silicon oxide” includes compounds having the formula SiOₙ, where 1≤n≤2, where n can be an integer or non-integer values. “Silicon oxide” can include sub-stoichiometric compounds such as SiO_{1.8}. “Silicon oxide” also includes silicon dioxide (SiO₂) and silicon monoxide (SiO). “Silicon oxide” also includes both natural and synthetic variations and also includes any and all crystalline and molecular structures, including tetrahedral coordination of oxygen atoms surrounding a central silicon atom. “Silicon oxide” also includes amorphous silicon oxide and silicates.

Carbides include but are not limited to metal carbides, semiconductor carbides, and dielectric carbides. Carbides include undoped carbides and doped carbides. One example carbide is silicon carbide.

Nitrides include but are not limited to metal nitrides, semiconductor nitrides, and dielectric nitrides. Nitrides include undoped nitrides and doped nitrides. One example nitride is undoped silicon nitride. “Silicon nitride” is referred to herein as including any and all stoichiometric possibilities for SiₓN_{y}, including integer values of x and y and non-integer values of x and y, such as x=3 and y−4. For example, “silicon nitride” includes compounds having the formula SiNₙ, where 1≤n≤2, where n can be an integer or non-integer values. “Silicon nitride” can include sub-stoichiometric compounds such as SiN_{1.8}. “Silicon nitride” also includes Si₃N₄ and silicon nitride with trace and/or interstitial hydrogen (SiNH) and silicon nitride with trace amounts of and/or interstitial oxygen (SiON). “Silicon nitride” also includes both natural and synthetic variations and also includes any and all lattice, crystalline, and molecular structures, including trigonal alpha-silicon nitride, hexagonal beta-silicon nitride, and cubic gamma-silicon nitride. “Silicon nitride” also includes amorphous silicon nitride and can include silicon nitride having trace amounts of impurities.

In some embodiments, the mixed material stack includes some regions having silicon oxide and some regions having alternating silicon oxide and silicon nitride layers, each layer having a thickness of about 10 Å to about 50 Å. The mixed material stack may have an overall thickness of about 8000 nm to about 20000 nm. The mixed material stack may be formed over a semiconductor substrate. The mixed material stack may have no features etched thereon. In some embodiments, some features may be etched thereon. In some embodiments, the mixed material stack may have one or more etching masks thereon.

In operation 203, the mixed material stack is exposed to etching gases to partially form negative features in the mixed material stack. Any etching process used to etch a mixed material stack may be used in operation 203. The etching gas may include a halogen-containing gas, such as a fluorocarbon gas or a hydrofluorocarbon gas. Example etchants for etching silicon oxide include nitrogen trifluoride, fluoroform (CHF₃), octafluorocyclobutane (C₄F₈), tetrafluoromethane (CF₄), and combinations thereof. Example etchants for etching silicon carbide, silicon nitride, silicon, tungsten, ruthenium, copper, cobalt, and molybdenum for feature fill using these materials include hydrobromic acid (HBr), fluoromethane (CH₃F), chlorine (Cl₂), silicon tetrafluoride (SiF₄), tetrafluoromethane (CF₄), boron trichloride (BCl), fluoroform (CHF₃) and combinations thereof. In various embodiments, etchants may be flowed with one or more inert gases, such as argon.

In various embodiments, operation 203 is a continuous etching process by continuously flowing one or more etching gases. In various embodiments, operation 203 involves a cyclic etching process by exposing the mixed material stack to temporally separated pulses of etching gases. In some embodiments, etching in operation 203 is performed by igniting a plasma. In some embodiments, the plasma is ignited using radio frequency plasma. In various embodiments, the plasma is generated in-situ. In some embodiments, plasma may be generated remotely in a remote plasma chamber prior to delivering the process chamber housing the substrate. In various embodiments, the plasma is ignited while flowing the etching gas(es) using a plasma power between about 10000 W and about 50000 W for a single-station chamber.

In various embodiments, operation 203 involves a high plasma power etching process using at least one halogen-containing gas. In one example, operation 203 involves at least one cycle of etching performed by (i) introducing a fluorocarbon gas in a pulse, and (2) introducing a hydrofluorocarbon gas in a pulse, both pulses performed while igniting a plasma using high plasma power, such as at least about 30000 W or greater for single-station chamber. The single-station chamber may be on a platform that can hold up to about 10 chambers. Introducing a hydrofluorocarbon gas may be referred to as a hydrogen-rich etching operation. In some embodiments, operation 203 is performed by alternating between a fluorocarbon gas exposure and a hydrogen-rich fluorocarbon gas exposure. The flow rate of the etching gases depend on the etching gas mixture and composition, on the chamber size, and other factors. In some embodiments, the flow rate of the etching gas(es) is about 4 sccm for a 20 second exposure.

In various embodiments, operation 203 may be performed at a chamber pressure of about 10 milliTorr to about 50 milliTorr. In various embodiments, operation 203 may be performed using a substrate temperature of about −20° C. to about 100° C. Substrate temperature will be understood to be the temperature at which a pedestal holding the substrate is set at.

In operation 205, a metal-containing additive gas is introduced at controlled mild process conditions to provide metal to exposed surfaces of the mixed material stack. The metal provided reduces and prevents line bending, maintains structural integrity and profile of the feature structure, and minimizes the formation of metal byproducts on surfaces of the mixed material stack. The metal-containing additive gas may be a tungsten-containing gas. In some embodiments, the metal-containing additive gas is a halogen-containing gas. In various embodiments, the metal-containing additive gas is a volatile metal compound. In some embodiments, the metal-containing additive gas is tungsten hexafluoride (WF₆). Additional non-limiting examples include molybdenum hexafluoride (MoF₆), titanium tetrachloride (TiCl₄), tin(IV) chloride (SnCl₄), tungsten hexacarbonyl (W(CO)₆), molybdenum hexacarbonyl (Mo(CO)₆), tetrakis(diethylamino)titanium(IV) ([(C₂H₅)₂N]₄Ti), (C₅H₅)WH₂, and combinations thereof. In some embodiments, the metal-containing additive gas is diluted in an inert gas, such as argon, krypton, helium, or combinations thereof.

The controlled mild process conditions include one or more of low plasma power, high chamber pressure, and low temperature. In various embodiments, the plasma power used in operation 205 is less than the plasma power used in operation 203. In some embodiments, the plasma power used in operation 205 is less than about 20% of the plasma power used in operation 203. In some embodiments, the plasma power used in operation 205 is less than about 10% of the plasma power used in operation 203. In some embodiments, the plasma power used in operation 205 is about 1% to about 2% of the plasma power used in operation 203. In some embodiments, the plasma power used in operation 205 is about 200 W for a 4-station station.

In various embodiments, the chamber pressure used in operation 205 is greater than the chamber pressure used in operation 203. In some embodiments, the chamber pressure used in operation 205 is 1.5 times greater than the chamber pressure used in operation 203. In some embodiments, the chamber pressure used in operation 205 is 4 times greater than the chamber pressure used in operation 203. In some embodiments, the chamber pressure is about 20 milliTorr to about 100 milliTorr.

In various embodiments, the substrate temperature used in operation 205 is less than the substrate temperature used in operation 203. In some embodiments, the substrate temperature used in operation 205 is less than about 20° C. In some embodiments, the substrate temperature used in operation 205 is less than about 60° C. In some embodiments, the substrate temperature used in operation 205 is about 20° C. to about 100° C.

The selection of which process conditions to use under milder conditions in operation 205 depends on the material being etched and the structure of the mixed material stack. In some embodiments, at least one process condition is modulated. In some embodiments, more than one process condition is modulated. In some embodiments, only plasma power is modulated. In some embodiments, only pressure is modulated. In some embodiments, only substrate temperature is modulated. In some embodiments, only plasma power and pressure are modulated. In some embodiments, only plasma power and substrate temperature are modulated. In some embodiments, only pressure and substrate temperature are modulated. In some embodiments, plasma power, pressure, and temperature are all modulated. In some embodiments, other process conditions are modulated—either such conditions are modulated alone or with one or more other process conditions. For example, the duration of exposure to the metal-containing additive gas may be modulated. Very little amount of metal can be used in operation 205 to achieve the effects of using the metal-containing additive gas. In another example, the amount and selection of dilution gas flowed with the metal-containing additive gas may be modulated. Example dilution gases include argon or krypton. Dilution gases are inert gases and can be co-flowed with the metal-containing additive gas.

The flow rate of the metal-containing additive gas may depend on the chamber size and other factors. In some embodiments, the metal-containing additive gas flow rate is less than about 25% of the flow rate of gases used during operation 203. In some embodiments, the flow rate of the metal-containing additive gas is about 0.5 sccm to about 5 sccm. The flow rate of the dilution gas or inert gas flowed with a metal-containing additive gas depends on the flow rate of the metal-containing additive gas. For lower flow rates of the metal-containing additive gas, the dilution gas or inert gas may be flowed at a higher flow rate or composition percentage of the total flow rate to allow effective delivery of the gases to a process chamber housing the substrate. In some embodiments, the ratio of the flow rate of the metal-containing additive gas to the flow rate of the inert gas is about 1:40 to about 1:100.

In some embodiments, operation 205 is performed for a particular duration. For example, operation 205 may be performed as a “flash” operation after some etching is performed in operation 203, before completing etching of features in the mixed material stack. A “flash” operation may last a duration of about 1 second to about 30 seconds or about 10 seconds to about 20 seconds. The duration of operation 205 may be increased as etching is performed deeper within a mixed material stack.

In some embodiments, operations 203 and 205 are performed in different chambers. In some embodiments, operations 203 and 205 are performed in the same chamber. In some embodiments, operations 203 and 205 are performed without breaking vacuum. For example, in some embodiments operations 203 and 205 are performed in separate stations in a multi-station chamber without breaking vacuum. Disclosed embodiments promote efficiency since deposition and etching may be performed in the same chamber or in the same tool. In some embodiments, the process chamber is purged between operation 203 and operation 205. Purging the chamber may involve flowing a purge gas or a sweep gas, which may be a carrier gas used in other operations or may be a different gas. Example purge gases include argon, nitrogen, hydrogen, and helium. In various embodiments, the purge gas is an inert gas. Example inert gases include argon, nitrogen, and helium. In some embodiments, purging may involve evacuating the chamber. In some embodiments, purging may include one or more evacuation subphases for evacuating the process chamber. Alternatively, it will be appreciated that purging may be omitted in some embodiments. Purging may be performed for any suitable duration, such as between about 0.1 seconds and about 2 seconds.

In operation 207, operation 203 is optionally repeated. In operation 209, operation 205 is optionally repeated. In some embodiments, operation 205 is performed before operation 203. In some embodiments, operation 205 is performed after operation 203. In some embodiments, operations 203 and 205 are performed numerous times. Repeated operations of operation 203 and operation 205 may be performed sequentially, or may be performed variably. In some embodiments, operation 205 is periodically performed during operation 203. In some embodiments where operation 205 involves cyclic exposures to etching gases, operation 205 is inserted after every n cycles, where n is any integer equal to or greater than 1. In some embodiments, operation 205 is occasionally performed every n cycles, or is performed after all cycles are performed in operation 203, or is performed depending on the condition of the mixed material stack, the composition of sidewalls in the features formed from etching in operation 203, and other factors.

Operation 205 is performed to achieve reduced feature twisting, reduced feature distortion, improved or maintained feature ellipticity (such as maintaining a feature ellipticity of about 1 for certain features, or having a feature ellipticity delta between the incoming feature and the resulting feature of about 0), reduced sidewall roughness, and reduced or eliminated chipping effects.

### Apparatus

The methods described herein may be performed by any appropriate apparatus. In various embodiments, an appropriate apparatus includes a processing chamber configured for plasma processing, and a controller configured to perform any of the methods described herein. As mentioned above, example apparatus that may be used to perform the etching processes described herein include the FLEX™ and VANTEX™ product families of reactive ion etch reactors available from Lam Research Corporation of Fremont, CA.

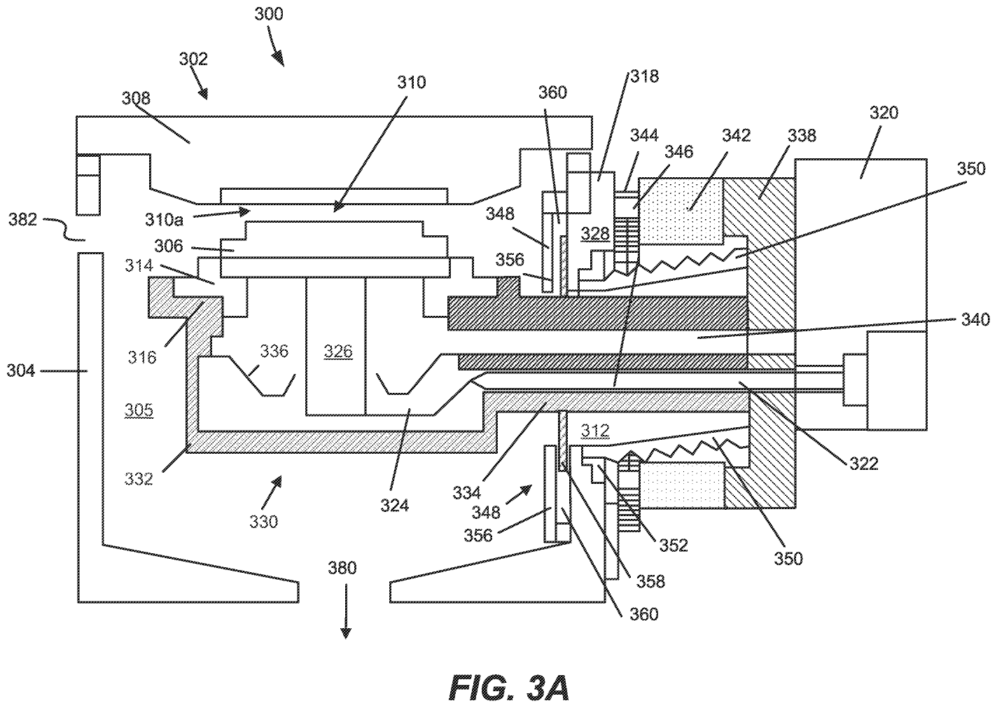

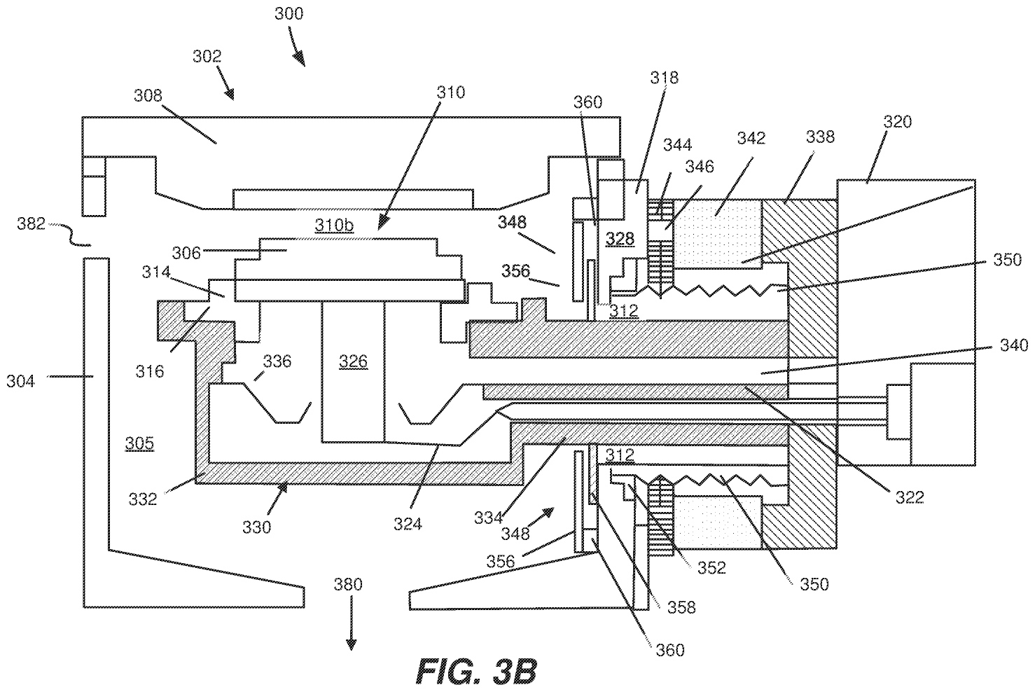

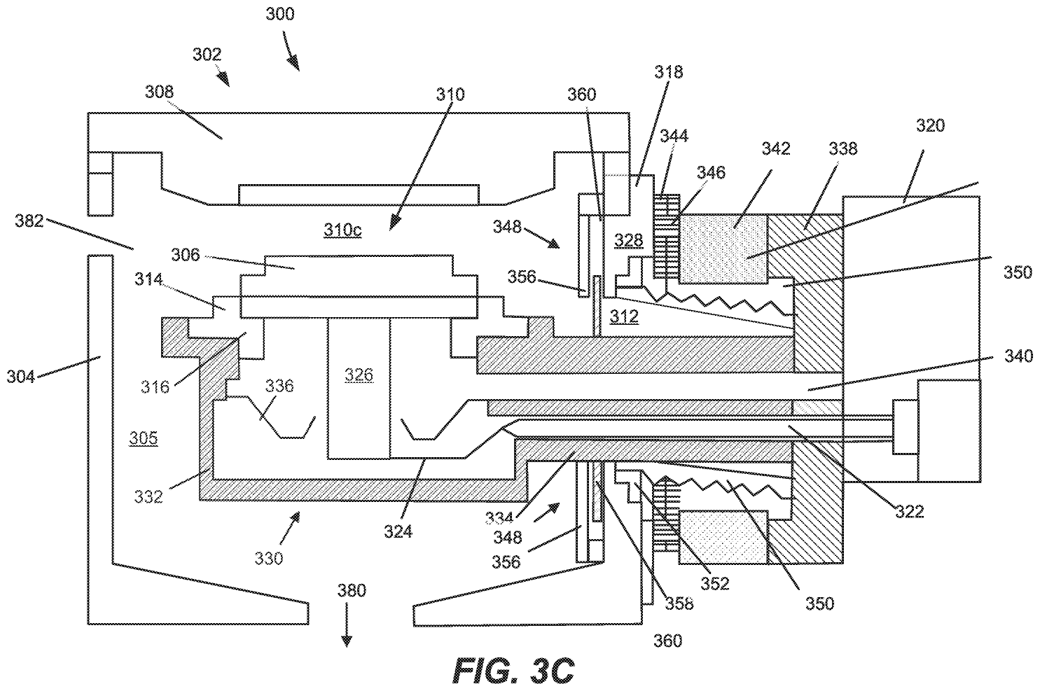

FIGS. 3A-3C illustrate an embodiment of an adjustable gap capacitively coupled confined radio frequency (RF) plasma reactor 300 that may be used for performing the etching operations described herein. As depicted, a vacuum chamber 302 includes a chamber housing 304, surrounding an interior space housing a lower electrode 306. In an upper portion of the chamber 302 an upper electrode 308 is vertically spaced apart from the lower electrode 306. Planar surfaces of the upper and lower electrodes 308, 306 are substantially parallel and orthogonal to the vertical direction between the electrodes. Preferably the upper and lower electrodes 308, 306 are circular and coaxial with respect to a vertical axis. A lower surface of the upper electrode 308 faces an upper surface of the lower electrode 306. The spaced apart facing electrode surfaces define an adjustable gap 310 therebetween. During operation, the lower electrode 306 is supplied RF power by an RF power supply (match) 320. RF power is supplied to the lower electrode 306 though an RF supply conduit 322, an RF strap 324 and an RF power member 326. A grounding shield 336 may surround the RF power member 326 to provide a more uniform RF field to the lower electrode 306. As described in commonly-owned U.S. Pat. No. 7,732,728, the entire contents of which are herein incorporated by reference, a wafer is inserted through wafer port 382 and supported in the gap 310 on the lower electrode 306 for processing, a process gas is supplied to the gap 310 and excited into plasma state by the RF power. The upper electrode 308 can be powered or grounded.

In cases where one or more species delivered to the plasma reactor 300 is stored as a liquid, a modified gas delivery system (not shown) may be used. For instance, the modified gas delivery system may include hardware (e.g., bubbler, vaporizer, etc.) for vaporizing a liquid phase species, as well as appropriate plumbing (e.g., high temperature gas lines and valves) and control equipment (e.g., high temperature mass flow controller and/or liquid flow controller) for implementing the reactant delivery.

In the embodiment shown in FIGS. 3A-3C, the lower electrode 306 is supported on a lower electrode support plate 316. An insulator ring 314 interposed between the lower electrode 306 and the lower electrode. Support plate 316 insulates the lower electrode 306 from the support plate 316.

An RF bias housing 330 supports the lower electrode 306 on an RF bias housing bowl 332. The bowl 332 is connected through an opening in a chamber wall plate 318 to a conduit support plate 338 by an arm 334 of the RF bias housing 330. In a preferred embodiment, the RF bias housing bowl 332 and RF bias housing arm 334 are integrally formed as one component, however, the arm 334 and bowl 332 can also be two separate components bolted or joined together.

The RF bias housing arm 334 includes one or more hollow passages for passing RF power and facilities, such as gas coolant, liquid coolant, RF energy, cables for lift pin control, electrical monitoring and actuating signals from outside the vacuum chamber 302 to inside the vacuum chamber 302 at a space on the backside of the lower electrode 306. The RF supply conduit 322 is insulated from the RF bias housing arm 334, the RF bias housing arm 334 providing a return path for RF power to the RF power supply 320. A facilities conduit 340 provides a passageway for facility components. Further details of the facility components are described in U.S. Pat. Nos. 5,948,704 and 7,732,728 and are not shown here for simplicity of description. The gap 310 is preferably surrounded by a confinement ring assembly or shroud (not shown), details of which can be found in commonly owned published U.S. Pat. No. 7,740,736 herein incorporated by reference. The interior of the vacuum chamber 302 is maintained at a low pressure by connection to a vacuum pump through vacuum portal 380.

The conduit support plate 338 is attached to an actuation mechanism 342. Details of an actuation mechanism are described in commonly-owned U.S. Pat. No. 7,732,728 incorporated herein by above. The actuation mechanism 342, such as a servo mechanical motor, stepper motor or the like is attached to a vertical linear bearing 344, for example, by a screw gear 346 such as a ball screw and motor for rotating the ball screw. During operation to adjust the size of the gap 310, the actuation mechanism 342 travels along the vertical linear bearing 344. FIG. 3A illustrates the arrangement when the actuation mechanism 342 is at a high position on the linear bearing 344 resulting in a small gap 310 a. FIG. 3B illustrates the arrangement when the actuation mechanism 342 is at a mid position on the linear bearing 344. As shown, the lower electrode 306, the RF bias housing 330, the conduit support plate 338, the RF power supply 320 have all moved lower with respect to the chamber housing 304 and the upper electrode 308, resulting in a medium size gap 310 b.

FIG. 3C illustrates a large gap 310 c when the actuation mechanism 342 is at a low position on the linear bearing. Preferably, the upper and lower electrodes 308, 306 remain co-axial during the gap adjustment and the facing surfaces of the upper and lower electrodes across the gap remain parallel.

This embodiment allows the gap 310 between the lower and upper electrodes 306, 308 in the CCP chamber 302 during multi-step process recipes (BARC, HARC, and STRIP etc.) to be adjusted, for example, in order to maintain uniform etch across a large diameter substrate such as 300 mm wafers or flat panel displays. In particular, this chamber pertains to a mechanical arrangement that permits the linear motion necessary to provide the adjustable gap between lower and upper electrodes 306, 308.

FIG. 3A illustrates laterally deflected bellows 350 sealed at a proximate end to the conduit support plate 338 and at a distal end to a stepped flange 328 of chamber wall plate 318. The inner diameter of the stepped flange defines an opening 312 in the chamber wall plate 318 through which the RF bias housing arm 334 passes. The distal end of the bellows 350 is clamped by a clamp ring 352.

The laterally deflected bellows 350 provides a vacuum seal while allowing vertical movement of the RF bias housing 330, conduit support plate 338 and actuation mechanism 342. The RF bias housing 330, conduit support plate 338 and actuation mechanism 342 can be referred to as a cantilever assembly. Preferably, the RF power supply 320 moves with the cantilever assembly and can be attached to the conduit support plate 338. FIG. 3B shows the bellows 350 in a neutral position when the cantilever assembly is at a mid position. FIG. 3C shows the bellows 350 laterally deflected when the cantilever assembly is at a low position.

A labyrinth seal 348 provides a particle barrier between the bellows 350 and the interior of the plasma processing chamber housing 304. A fixed shield 356 is immovably attached to the inside inner wall of the chamber housing 304 at the chamber wall plate 318 so as to provide a labyrinth groove 360 (slot) in which a movable shield plate 358 moves vertically to accommodate vertical movement of the cantilever assembly. The outer portion of the movable shield plate 358 remains in the slot at all vertical positions of the lower electrode 306.

In the embodiment shown, the labyrinth seal 348 includes a fixed shield 356 attached to an inner surface of the chamber wall plate 318 at a periphery of the opening 312 in the chamber wall plate 318 defining a labyrinth groove 360. The movable shield plate 358 is attached and extends radially from the RF bias housing arm 334 where the arm 334 passes through the opening 312 in the chamber wall plate 318. The movable shield plate 358 extends into the labyrinth groove 360 while spaced apart from the fixed shield 356 by a first gap and spaced apart from the interior surface of the chamber wall plate 318 by a second gap allowing the cantilevered assembly to move vertically. The labyrinth seal 348 blocks migration of particles spalled from the bellows 350 from entering the vacuum chamber interior 305 and blocks radicals from process gas plasma from migrating to the bellows 350 where the radicals can form deposits which are subsequently spalled.

FIG. 3A shows the movable shield plate 358 at a higher position in the labyrinth groove 360 above the RF bias housing arm 334 when the cantilevered assembly is in a high position (small gap 310 a). FIG. 3C shows the movable shield plate 358 at a lower position in the labyrinth groove 360 above the RF bias housing arm 334 when the cantilevered assembly is in a low position (large gap 310 c). FIG. 3B shows the movable shield plate 358 in a neutral or mid position within the labyrinth groove 360 when the cantilevered assembly is in a mid position (medium gap 310 b). While the labyrinth seal 348 is shown as symmetrical about the RF bias housing arm 334, in other embodiments the labyrinth seal 348 may be asymmetrical about the RF bias arm 334.

The apparatus shown in FIGS. 3A-3C includes a controller that is configured to perform the methods described herein. In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### EXPERIMENTAL

An experiment was conducted to etch high aspect ratio features into an ONON stack and into an oxide only material using etching gases without using a metal-containing additive gas. At the bottoms of the high aspect ratio features in the ONON stack, etching did not reach the etch stop layer at the bottom of the stack in some regions but reached it in other regions which resulted in depth loading issues. The profiles of the holes showed some partially etched features. Similar substrates were exposed to etching gases while using tungsten hexafluoride additive gas at low plasma power and high pressure during etching. The resulting substrates showed improved maintenance of profile shape, reduced bowing on the oxide substrate, and improved depth loading.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for processing substrates, the method comprising:
providing a substrate having a mixed material stack;
exposing the mixed material stack to one or more etching gases and igniting a first plasma at a first plasma power to partially etch a feature into the mixed material stack to form a partially etched mixed material stack; and
exposing the partially etched mixed material stack to a second plasma having generated from igniting a metal-containing additive gas at a second plasma power, wherein the second plasma power is less than the first plasma power.

2. The method of claim 1, wherein the metal-containing additive gas comprises a halogen.

3. The method of claim 1, wherein the metal-containing additive gas comprises a metal selected from the group consisting of tungsten, tin, molybdenum, and titanium.

4. The method of claim 1, wherein the second plasma power is less than about 1% to about 10% of the first plasma power.

5. The method of claim 1, wherein exposing the partially etched mixed material stack to the second plasma is performed at a first chamber pressure greater than a second chamber pressure used during the exposing of the mixed material stack to the one or more etching gases.

6. The method of claim 1, wherein the exposing the partially etched mixed material stack to the second plasma is performed using a first substrate temperature less than second substrate temperature used during the exposing of the mixed material stack to the one or more etching gases.

7. The method of claim 1, wherein the exposing the partially etched mixed material stack to the second plasma is performed for a duration less than about 20 seconds.

8. The method of claim 1, wherein the one or more etching gases include at least one gas comprising a fluorine and a carbon atom.

9. The method of claim 1, wherein the metal-containing additive gas is diluted in an inert gas.

10. An apparatus for processing substrates, the apparatus comprising:
one or more process chambers, each process chamber comprising a chuck;
a plasma generator;
a first gas source for containing one or more etching gases;
a second gas source for containing a metal-containing additive gas;
one or more gas inlets into the process chambers and associated flow-control hardware for delivering gases from the first gas source and the second gas source to the one or more process chambers; and
a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to at least control the flow-control hardware to:
cause a substrate to be provided to a first of the one or more process chambers;
cause a first plasma to be generated at a first plasma power using one or more etching gases; and
cause a second plasma to be generated at a second plasma power using a metal-containing additive gas,
wherein the second plasma power is less than the first plasma power.
